(19) United States
(12) Patent Application Publication
(10) Pub. No.: US 2026/0255495 A1
(43) Pub. Date: Aug. 27, 2026

(54) METHOD FOR FORMING CONDUCTIVE STRUCTURE

(71) Applicant: DUPONT ELECTRONICS, INC., Wilmington, DE (US)

(72) Inventors: CHING MAO HUANG, HSINCHU CITY (TW); YEN MING TSENG, HSINCHU CITY (TW); TING HSUAN CHANG, HSINCHU CITY (TW); TSUNG HAN TSAI, HSINCHU CITY (TW); LI YEN LIN, HSINCHU CITY (TW)

(21) Appl. No.: 19/537,747

(22) Filed: Feb. 12, 2026

Related U.S. Application Data
(60) Provisional application No. 63/762,493, filed on Feb. 24, 2025.

(51) Int. Cl. H05K 3/12

(52) U.S. Cl. CPC H05K 3/1283; H05K 3/1275; H05K 2203/105; H05K 2203/107; H05K 2203/1131

(57) ABSTRACT

The present disclosure provides a method for forming a conductive structure. The method comprises: i) applying a conductive ink composition on a substrate; and ii) performing an IR laser irradiation on the applied conductive ink composition. The IR laser irradiation is performed with a wavelength of 800 nm to 1150 nm and a pulse duration of 100 femtoseconds to 5000 femtoseconds, and is operated at an absolute value of defocused Z offset ranging from 2 mm to 40 mm.

### FIELD OF THE INVENTION

The present disclosure provides a method for forming a conductive structure, which comprises a step of laser irradiation.

### BACKGROUND OF THE INVENTION

Conventionally, conductive structures of an electronic circuit can be formed by photolithography, where unwanted portions of a metal layer are etched away to provide a desired pattern. However, photolithography typically involves high energy and water consumption, numerous production steps and a considerable amount of wasted materials.

As an alternative to photolithography, printing technology (such as pressure-controlled direct dispensing and electrohydrodynamic (EHD) dispensing) has been studied and developed. In contrast to photolithography, this technology is an additive process rather than a subtractive process and has the advantage of producing less wasted materials. Generally, printing technology involves extrusion of an ink composition comprising solvent and metal particles though a nozzle onto a surface of a substrate, drying the printed ink composition to remove solvent and sintering the metal particles in the printed ink composition to form continuous metal lines constituting a wiring pattern.

Traditionally, the drying and sintering processes are performed thermally, where the printed ink composition is under thermal heating alone with the substrate carrying it at a high temperature (such as 150° C.-350° C.) to sinter metal particles. Applications of such thermal sintering processes are restricted by the thermal stability of the ink composition and substrate, especially with materials having a lower glass transition temperature and/or decomposition temperature such as flexible polymers or paper.

In view of the shortcomings of thermal sintering, photonic sintering has been developed to perform sintering locally and at a comparably lower temperature. Particularly, laser sintering has attracted increasing attention recently. However, since laser is generally a concentrated energy source in nature, it should be handled carefully, otherwise failure such as cracking, peeling, and ablation of materials may take place. To ensure sufficient sintering effect while also minimizing heat accumulation, complicated process control may be needed. In some previous works, multiple irradiations are needed, sometimes even with different light sources of different wavelengths. There remains a need in the field to provide a method addressing these issues.

### SUMMARY OF THE INVENTION

In view of the aforementioned technical problems, the present disclosure aims to provide a viable method that can optimize laser sintering process and is able to produce conductive structures with good appearance, resistivity and adhesion to substrate.

Accordingly, an objective of the present disclosure is to provide a method for forming a conductive structure, comprising:
i) applying a conductive ink composition on a substrate; and
ii) performing an IR laser irradiation on the applied conductive ink composition,
wherein the IR laser irradiation is performed with a wavelength of 800 nm to 1150 nm and a pulse duration of 100 femtoseconds to 5000 femtoseconds; and
wherein the IR laser irradiation is operated at an absolute value of defocused Z offset ranging from 2 mm to 40 mm.

In an embodiment of the present disclosure, the IR laser irradiation is operated at an output power of 0.1 W to 100 W.

In an embodiment of the present disclosure, the IR laser irradiation is operated at a repetition rate of 20 kHz to 2000 kHz.

In an embodiment of the present disclosure, the IR laser irradiation is operated at a scan speed of 0.1 mm/s to 5000 mm/s.

In an embodiment of the present disclosure, the IR laser irradiation is operated at a hatch pitch of 1 μm to 100 μm.

In an embodiment of the present disclosure, the IR laser irradiation is performed in one step with a single wavelength.

In an embodiment of the present disclosure, the applying is performed by pressure-controlled direct dispensing, electrohydrodynamic (EHD) dispensing, inkjet printing, aerosol printing, screen printing, flexography printing, gravure printing, off-set printing, or a combination thereof.

In an embodiment of the present disclosure, the conductive ink composition comprises: metal particles, a binder, and a solvent.

In an embodiment of the present disclosure, the substrate is selected from the group consisting of Cu, Ag, Ti, Ti—Al—Ti stack, glass, Al₂O₃, BaTiO₃, AlN, TiO₂, ZrO₂, polyimide (PI), polyethylene terephthalate (PET), polyethylene naphthalate (PEN), polyethylene furandicarboxylate (PEF), polycarbonate (PC), poly(methyl methacrylate) (PMMA), cyclic olefin polymer (COP), fiber-reinforced composite, and combinations thereof.

To render the above objectives, technical features, and advantages of the present disclosure more apparent, the present disclosure will be described in detail with reference to some embodiments hereinafter.

### DETAILED DESCRIPTION OF THE INVENTION

Hereinafter, some embodiments of the present disclosure will be described in detail. However, the present disclosure may be embodied in various embodiments, and the protection scope of the present disclosure should not be limited to those described in the specification.

As used herein, the expressions “a”, “the”, or the like recited in the specification and in the claims should include both the singular and the plural forms unless stated otherwise.

As used herein, the terms “first”, “second”, or the like recited in the specification and in the claims are only used to distinguish the illustrated elements or components and do not represent any priority.

As used herein, the term “focus” refers to a point where the incident light converges to. In embodiments where two or more lenses or mirrors are used, the “focus” should be interpreted as the “equivalent focus” resulting from the combination of these lenses or mirrors.

The method of the present disclosure is described in detail below.

In the present disclosure, the method for forming a conductive structure comprises: i) applying a conductive ink composition on a substrate; and ii) performing an IR laser irradiation on the applied conductive ink composition.

The method for applying conductive ink composition is not particularly limited and can be any method known in the art. For example, the conductive ink composition can be applied by pressure-controlled direct dispensing, electrohydrodynamic (EHD) dispensing, inkjet printing, aerosol printing, screen printing, flexography printing, gravure printing, off-set printing, or a combination thereof. In an embodiment of the present disclosure, the conductive ink composition is applied to the substrate by pressure-controlled direct dispensing. In another embodiment of the present disclosure, the conductive ink composition is applied to the substrate by electrohydrodynamic (EHD) dispensing.

After a conductive ink composition is applied to a substrate, it is further processed to form a conductive structure on the substrate. Since a conductive ink composition usually comprises a solvent for the ease of handling, the solvent needs to be removed so that conductive components (usually metal particles) in the conductive ink composition can be brought into contact with one another to be further fused together. These processes are generally referred to as “drying” and “sintering” processes. In the present disclosure, the drying and sintering processes are performed by IR irradiation using IR pulse laser. In one embodiment, the drying and sintering processes are both concluded in the same one-step IR laser irradiation process.

In the IR laser irradiation, the solvent is removed through evaporation, allowing the metal particles to come into contact with one another and form necks that fuse them together. Meanwhile, some conductive ink compositions also comprise a binder. In such embodiments, the binder can be partially photo-degraded and evaporated during the IR laser irradiation, leaving a portion of remaining binder that may contribute to binding the metal particles together as well as binding the metal particles to the substrate.

In an embodiment of the present disclosure, the IR laser irradiation is performed in one step with a single wavelength. This simplifies the laser sintering process compared to some previous works requiring multiple irradiations.

The method of the present disclosure utilizes an IR laser irradiation primarily for drying out the solvent and sintering the conductive components (usually metal particles). To achieve targeted drying and sintering performance, several operation parameters in the IR laser irradiation process can be considered and adjusted for optimal results. These operation parameters are described in detail below.

In the present disclosure, the IR laser irradiation is performed with a wavelength of 800 nm to 1150 nm. It is found that within the range, the solvent can be removed at an optimal evaporation rate, and the binder, if used, can be remained, partially evaporated or decomposed. As a result, a conductive structure produced using IR pulse laser whose wavelength is within the range above may have better appearance, resistivity and adhesion to substrate compared to those produced using such as green pulse laser or UV pulse laser. Specific examples of such IR laser include those having a wavelength of 808 nm, 830 nm, 850 nm, 905 nm, 915 nm, 920 nm, 940 nm, 950 nm, 980 nm, 1030 nm, 1053 nm, 1060 nm, 1064 nm, or 1150 nm. In an embodiment of the present disclosure, the IR laser has a wavelength of 1030 nm.

In the present disclosure, the IR laser irradiation is performed with a pulse duration of 100 femtoseconds (fs) to 5000 femtoseconds (fs). The pulse duration is defined as the full width at half-maximum (FWHM) of a laser pulse in the pulse energy-to-time diagram. It is found that a longer pulse duration, such as in nanosecond order, may create melt zone or cause heat damage on the applied conductive ink composition or the substrate. In an embodiment of the present disclosure, the pulse duration can be 100 fs to 5000 fs, or 250 fs to 2500 fs, or 400 fs to 1000 fs. For example, the pulse duration can be 100 fs, 150 fs, 200 fs, 300 fs, 400 fs, 500 fs, 600 fs, 700 fs, 800 fs, 900 fs, 1000 fs, 1200 fs, 1500 fs, 2000 fs, 2500 fs, 3000 fs, 3500 fs, 4000 fs, 4500 fs, or 5000 fs, or within a range between any two of the values described herein.

In the present disclosure, the IR laser irradiation is operated using IR pulse laser at an absolute value of defocused Z offset ranging from 2 mm to 40 mm. The defocused Z offset refers to a distance between the focus of the laser and a first surface of the applied conductive ink composition, i.e., the surface of the applied conductive ink composition facing away from the substrate. If the focus is exactly on the first surface, the value of the defocused Z offset is zero. Meanwhile, if the laser hits the first surface before converging to the focus, the value of the defocused Z offset is defined as negative; and if the laser hits the first surface after converging to the focus, the value of the defocused Z offset is defined as positive. When the laser hits the first surface, it creates a laser spot on the first surface. In the present disclosure, the first surface is intentionally moved away from the focus (also referred to as “offset approach” hereinafter) to control the laser spot size and laser pulse fluence so that satisfactory sintering performance can be provided while heat damage can be prevented. In an embodiment of the present disclosure, the absolute value of the defocused Z offset can be 2 mm to 35 mm, or 2 mm to 30 mm. For example, the defocused Z offset can be −30 mm, −25 mm, −20 mm, −15 mm, −10 mm, −5 mm, −4 mm, −3 mm, −2 mm, 2 mm, 3 mm, 3.5 mm, 4 mm, 5 mm, 10 mm, 15 mm, 20 mm, 25 mm, 27 mm, 30 mm, 35 mm, or 40 mm.

In an embodiment of the present disclosure, the IR laser irradiation is operated using IR pulse laser at an output power of 0.1 W to 100 W, or 0.1 W to 20 W, or 0.5 to 8 W. The output power is defined as the maximum energy (peak energy) in the pulse energy-to-time diagram. A higher output power may increase the likelihood to cause heat damage, while a lower output power may increase the likelihood of insufficient sintering.

In an embodiment of the present disclosure, the IR laser irradiation is operated using IR pulse laser at a repetition rate of 20 kHz to 2000 kHz, or 30 kHz to 1500 kHz, or 50 kHz to 1200 kHz. The repetition rate refers to the number of laser pulses emitted per unit time. For a fixed total energy, a higher pulse repetition rate means that energy is spread over more pulses, resulting in lower energy per pulse or lower output power of each pulse.

In an embodiment of the present disclosure, the IR laser irradiation is operated using IR pulse laser at a scan speed of 0.1 mm/s to 5000 mm/s, 10 mm/s to 1000 mm/s, 30 mm/s to 600 mm/s. The scan speed refers to the linear relative movement per unit time of the laser hit on the first surface of the applied conductive ink composition. The scan speed can be adjusted to tune the laser pulse fluence.

In an embodiment of the present disclosure, the IR laser irradiation is operated using IR pulse laser at a hatch pitch of 1 μm to 100 μm, 3 μm to 50 μm, 5 μm to 20 μm. The hatch pitch refers to a displacement set after the laser scans through a scanning line and before scanning another. It can be interpreted as a distance between two adjacent scanning lines. Likewise, the hatch pitch can be adjusted to tune the laser pulse fluence.

To form a conductive structure, the method of the present disclosure requires a conductive ink composition and a substrate. Materials that may be suitable for the conductive ink composition and the substrate are described in detail below.

The conductive ink composition generally comprises metal particles for imparting conductivity to the conductive structure made by the method, and a solvent for dissolving or dispersing the same. In an embodiment of the present disclosure, the conductive ink composition comprises metal particles, a binder and a solvent. The binder can be used to enhance the adhesion of the metal particles with one another and to the substrate.

The type of the metal particles is not particularly limited and can be selected based on the processibility, conductivity, appearance or availability. In an embodiment of the present disclosure, silver is used. In addition, the size of the metal particles can be selected depending on the process conditions, such as for optimal absorption of the light/heat source. In an embodiment of the present disclosure, the average diameter of the metal particles can be in nanoscale, such as ranging from 20 nm to 400 nm, or 50 nm to 350 nm, or 100 nm to 160 nm. In an embodiment of the present disclosure, the metal particles are silver nanoparticles having an average diameter of 80 nm, 100 nm, 130 nm, 150 nm, 200 nm, or 300 nm, or within a range between any two of the values described herein. The average diameter of the silver nanoparticles can be measured by using a dynamic light scattering particle size analyzer.

The type of the binder can be selected so that it is partially evaporated or decomposed under the predetermined light/heat source. Examples of the binder include but are not limited to poly(vinyl acetate), poly(vinyl alcohol) (PVA), polydioxanone (PDO), polyacrylamide (PAM), poly(glycolic acid) (PGA), poly-(ε-caprolactone) (PCL), poly(L-lactic acid) (PLLA), polyurethane (PU), polyacrylate, polyvinylpyrrolidone (PVP), poly(vinyl alcohol-co-ethylene), polyethylene glycol (PEG), poly(tetramethylene ether) glycol (PTMEG), ethyl cellulose (EC), cellulose acetate, hydroxypropylmethyl cellulose (HPMC), polyvinyl butyral (PVB), and combinations thereof. In a more specific embodiment, the binder is selected from the group consisting of polyurethane (PU), polyacrylate, polyvinylpyrrolidone (PVP), ethyl cellulose (EC), cellulose acetate, and hydroxypropylmethyl cellulose (HPMC). The aforementioned binders can be used alone or in combination.

The type of the solvent can be selected for sufficient dissolution or dispersion of other components of the conductive ink composition as well as for optimal evaporation rate under predetermined laser light source. The solvent can be used as a single component solvent or as a mixed solvent of two or more components. In an embodiment of the present disclosure, the solvent can be alkoxy alcohol or alkoxy ester, such as ethylene glycol monomethyl ether, diethylene glycol monomethyl ether, triethylene glycol monomethyl ether, polyethylene glycol monomethyl ether, ethylene glycol monopropyl ether, diethylene glycol monopropyl ether, ethylene glycol monobutyl ether, diethylene glycol monobutyl ether (also referred to as butyl carbitol), triethylene glycol monobutyl ether, ethylene glycol monoisobutyl ether, ethylene glycol monohexyl ether, diethylene glycol monohexyl ether, ethylene glycol mono-2-ethylhexyl ether, and diethylene glycol mono-2-ethylhexyl ether. In an embodiment of the present disclosure, the solvent may have a boiling point ranging from 160° C. to 270° C., such as 160° C., 170° C., 200° C., 230° C., 250° C., or 270° C., or within a range between any two of the values described herein. In an embodiment of the present disclosure, the solvent does not comprise polyol and/or water.

In the embodiment where the conductive ink composition comprises metal particles, a binder and a solvent, the amount of the metal particles can range from 20 wt % to 95 wt %, or 20 wt % to 75 wt %, or 25 wt % to 70 wt %, based on a total weight of the conductive ink composition; the amount of the binder can range from 0.1 wt % to 20 wt %, or 2.5 wt % to 18 wt %, or 3 wt % to 15 wt %, based on a total weight of the conductive ink composition; and the amount of the solvent can range from 4.9 wt % to 79.9 wt %, or 10 wt % to 75 wt %, or 25 wt % to 65 wt %, based on a total weight of the conductive ink composition. Additionally, the amount of the binder based on a total weight of the binder and metal particles can range from 4 wt % to 45 wt %, or 4.5 wt % to 40 wt %, or 5 wt % to 35 wt %.

In an embodiment of the present disclosure, the conductive ink composition may further comprise optional components to adaptively improve the physical properties, chemical properties or processibility of the conductive ink composition. Examples of the optional components include but are not limited to additives such as adhesion promoters, coupling agents, rheology modifiers, dispersants, and surfactants.

In the present disclosure, the material for the substate is not particularly limited as long as it can withstand the energy of the light/heat source used in the IR laser irradiation step. In an embodiment of the present disclosure, the substrate can be Cu, Ag, Ti, Ti—Al—Ti stack, glass, Al₂O₃, BaTiO₃, AlN, TiO₂, ZrO₂, polyimide (PI), polyethylene terephthalate (PET), polyethylene naphthalate (PEN), polyethylene furandicarboxylate (PEF), polycarbonate (PC), poly(methyl methacrylate) (PMMA), cyclic olefin polymer (COP), fiber-reinforced composite, or a combination thereof.

Exemplary materials and preparation of the conductive ink composition and substrate are provided in the Example section below.

### EXAMPLES

### Materials Preparation

### Preparation Example PE1

A 20 wt % PVP solution was prepared by using an overhead mechanical stirrer in a 1 L vessel jacketed with a 4 C coolant. First, 240 g of butyl carbitol (available from Alfa Chemistry) were added to the vessel. 60 g of polyvinylpyrrolidone (PVP) (available from Thermo-Fischer) were weighed in a tray. To prevent PVP aggregation, 10 g of PVP were added slowly every 10 min until a total 60 g of PVP were present in the solution. The solution was stirred for 4 h until PVP was fully dissolved.

20 g of a silver nanoparticle slurry (SDU-005, available from DOWA) were weighted in a vial. A total of 10.2 g of the 20 wt % PVP solution prepared above were then stepwise added to the vial and mixed using a mixer (model number: ARE-500; available from Thinky). The steps were: adding 1 g of the PVP solution and mixing at 1000 rpm for 60 s twice, adding 2 g of the PVP solution and mixing at 1000 rpm for 60 s twice, adding 7.2 g of the PVP solution and mixing at 1000 rpm for 60 s twice. After the adding and mixing steps were completed, the conductive ink composition was obtained.

### Conductive Structure

For applying a conductive ink composition on a substrate, electrohydrodynamic (EHD) dispensing is performed. The conductive ink composition prepared in the Preparation Example PE1 is applied on a glass substrate to form parallel wiring lines on the substrate. The nozzle used has an inner diameter of 25 μm and an outer diameter of 55 μm and is set at a distance of 100 μm apart from the substrate. The conductive ink composition is loaded and then pumped through the nozzle and driven by a voltage of 1 kV, while the substrate is moved at a speed of 100 mm/s.

After the conductive ink composition is applied to the substrate, irradiation is performed at respective wavelengths in a laser micromachining system (available from CohPros) and operation parameters are varied for the Examples and Comparative Examples.

### Test Methods

### [Bulk Resistivity]

The bulk resistivity of a single wiring line on the substrate is tested by a standard four-probe method. A source meter (Keithley 2400, available from Keithley Instruments) is used for the measurement. A fixed current of 0.5 mA is applied and a real-time voltage drop of the wiring line is measured. Afterward, the bulk resistivity is calculated according to the following equation and is reported in μΩ·cm.

$$bulk resistivity = R \times A / L$$

wherein, R is the line resistance of the wiring line,
W is the width of the wiring line, and
A is the cross area of the wiring line (determined by Sensofar S neox)

### [Adhesion]

A pattern of 10 parallel wiring lines on a glass substrate is used as the specimen, and a cross-hatch tape test modified from ASTM D3359 is performed to evaluate the adhesion of the wiring lines to the substrate.

Initially, a first cut is made through the 10 parallel lines at 90° to the lines. Subsequently, a second cut parallel to and spaced 10 mm apart from the first cut is made through the 10 parallel lines to cut them into 10 line segments. Then, a third cut parallel to and spaced 10 mm apart from the second cut is made to produce another 10 line segments. The cutting process is repeated until a grid of 10×10 line segments is made. The grid is then softly brushed to remove debris produced from the cuts.

A tape (3M 610 Tape, available from 3M) is placed over the grid and pressed smoothly to ensure uniform contact with the line segments, which may be confirmed from uniform color tone of the contact area. Within 90 seconds from tape application, the tape is then removed by pulling it back at 180° along the direction of the line segments (perpendicular to the direction of cuts).

Afterward, the specimen is inspected under optical microscope (LSM900, available from Zeiss). The adhesion is evaluated according to the following criteria:
5B: all line segments remain intact and no detachment happens,
4B: less than 5% of the line segments are suffered from detachment,
3B: 5% to less than 15% of the line segments are suffered from detachment,
2B: 15% to less than 35% of the line segments are suffered from detachment,
1B: 35% to less than 65% of the line segments are suffered from detachment, and
0B: 65% or more of the line segments are suffered from detachment.

### Example E1 and Comparative Examples CE1-CE2

3 different specimens were prepared as described in the previous sections, where IR laser (Example E1), green light laser (Comparative Example CE1) and UV laser (Comparative Example CE2) were respectively used for the irradiation step. In the irradiation step, the pulse duration was set at 500 femtoseconds, the defocused Z offset was set at 3 mm, the output power was set at 2 W, the repetition rate was set at 100 kHz, the scan speed was set at 50 mm/s, and the hatch pitch was set at 10 μm. The 3 specimens were visually inspected and tested for bulk resistivity and adhesion according to the testing methods described in the previous section, and the results are summarized in Table 1.

TABLE 1

| | E1 | CE1 | CE2 |
|---|---|---|---|
| Light source | IR | Green | UV |
| Wavelength (nm) | 1030 | 515 | 343 |
| Pulse duration (fs) | 500 | 500 | 500 |
| Defocused Z offset (mm) | 3 | 3 | 3 |
| Output power (W) | 2 | 2 | 2 |
| Appearance | Fine | Cracking | Detached |
| | lines | | |
| Bulk resistivity | 30 | NA | NA |
| (μΩ · cm) | | | |
| Adhesion | 5B | 2B | 0B |

*NA means that the wiring lines are damaged or detached so that bulk resistivity measurement cannot be performed.

As shown in Table 1, fine wiring lines are made with IR laser irradiation (Example E1). On the other hand, irradiation with green light laser (Comparative Example CE1) or UV laser (Comparative Example CE2) under the same operation conditions only provide undesired results, i.e., poor appearance and adhesion.

### Examples E2-E4 and Comparative Examples CE3-CE4

A set of specimens were prepared as described in the previous sections, where the irradiation step is performed with one single IR laser having a wavelength of 1030 nm. In the irradiation step, the pulse duration was set at 500 femtoseconds, the output power was set at 3.9 W, the repetition rate was set at 100 kHz, the scan speed was set at 50 mm/s, the hatch pitch was set at 10 μm, and the defocused Z offset was varied for Examples E2-E4 and Comparative Examples CE3-CE4 according to Table 2. The specimens were visually inspected and tested for bulk resistivity and adhesion according to the testing methods described in the previous section, and the results are summarized in Table 2.

TABLE 2

| | CE3 | CE4 | E2 | E3 | E4 |
|---|---|---|---|---|---|
| Defocused Z offset (mm) | 0 | 1 | 2 | 3.5 | 4 |
| Output power (W) | 3.9 | 3.9 | 3.9 | 3.9 | 3.9 |
| Appearance | Burnt | Detached | Fine | Fine | Fine |
| | out | | lines | lines | lines |
| Bulk resistivity | NA | NA | 24 | 31.2 | 31.8 |
| (μΩ · cm) | | | | | |
| Adhesion | 0B | 0B | 5B | 5B | 5B |

*NA means that the wiring lines are damaged or detached so that bulk resistivity measurement cannot be performed.

As shown in Table 2, at an output power of 3.9 W, the wiring lines will burn if the IR laser hits the first surface of the applied conductive ink composition on focus, i.e., defocused Z offset=0 (Comparative Example CE3). When the defocused Z offset is adjusted to 1 mm (Comparative Example CE4), damage by burn can be reduced but the quality of the wiring lines is still poor since detaching from the substrate will occur. It is found that satisfactory results are obtained when the defocused Z offset is adjusted to 2 mm or more (Examples E2-E4), where the appearance, bulk resistivity and adhesion of the wiring lines are all good. This “offset approach” is different from conventional “on-focus approach” and is significant because it delivers desirable properties such as resistivity and resolution of the lines are still acceptable.

### Examples E5-E13

A set of specimens were prepared as described in the previous sections, where the irradiation step is performed with one single IR laser having a wavelength of 1030 nm. In the irradiation step, the pulse duration was set at 500 femtoseconds, while the defocused Z offset, the output power, the repetition rate, the scan speed, and the hatch pitch were varied for Examples E5-E13 according to Table 3. The specimens were visually inspected and tested for bulk resistivity and adhesion according to the testing methods described in the previous section, and the results are summarized in Table 3.

TABLE 3

| | E5 | E6 | E7 | E8 | E9 | E10 | E11 | E12 | E13 |
|---|---|---|---|---|---|---|---|---|---|
| Defocused Z offset (mm) | −25 | −15 | 15 | 20 | 25 | 25 | 25 | 25 | 27 |
| Output power (W) | 2.83 | 1.7 | 1.5 | 2.01 | 3.19 | 3.25 | 3.25 | 4 | 3.52 |
| Repetition rate (kHz) | 1000 | 1000 | 1000 | 1000 | 1000 | 1000 | 1000 | 100 | 1000 |
| Scan speed (mm/s) | 50 | 50 | 50 | 50 | 50 | 50 | 100 | 500 | 50 |
| Hatch pitch (μm) | 30 | 30 | 30 | 30 | 30 | 10 | 10 | 10 | 30 |
| Appearance | Fine | Fine | Fine | Fine | Fine | Fine | Fine | Fine | Fine |
| | lines | lines | lines | lines | lines | lines | lines | lines | lines |
| Bulk resistivity (μΩ · cm) | 24.8 | 28.4 | 20 | 18 | 18.3 | 16 | 24 | 36 | 21.3 |
| Adhesion | 5B | 5B | 5B | 5B | 5B | 5B | 5B | 5B | 5B |

As shown in Table 3, the results of Examples E5-E6 manifest that the “offset approach” shows the feasibility with negative defocused Z offset. Furthermore, the results of Examples E5-E13 show that operation parameters, including defocused Z offset, output power, repetition rate, scan speed and hatch pitch, can be adjusted for optimal results. From these results, Persons skilled in the art would appreciate that the method of the present disclosure has great potential to be exploited.

While some embodiments are provided in the specification, they are only illustrative of the present disclosure and are not intended to limit the protection scope of the present disclosure. Persons skilled in the art may proceed with a variety of modifications based on the disclosure as described without departing from the principle thereof. The protection scope of the present disclosure is as defined in the following claims.

What is claimed is:

1. A method for forming a conductive structure, comprising:
i) applying a conductive ink composition on a substrate; and
ii) performing an IR laser irradiation on the applied conductive ink composition,
wherein the IR laser irradiation is performed with a wavelength of 800 nm to 1150 nm and a pulse duration of 100 femtoseconds to 5000 femtoseconds; and
wherein the IR laser irradiation is operated at an absolute value of defocused Z offset ranging from 2 mm to 40 mm.

2. The method of claim 1, wherein the IR laser irradiation is operated at an output power of 0.1 W to 100 W.

3. The method of claim 1, wherein the IR laser irradiation is operated at a repetition rate of 20 kHz to 2000 kHz.

4. The method of claim 1, wherein the IR laser irradiation is operated at a scan speed of 0.1 mm/s to 5000 mm/s.

5. The method of claim 1, wherein the IR laser irradiation is operated at a hatch pitch of 1 μm to 100 μm.

6. The method of claim 1, wherein the IR laser irradiation is performed in one step with a single wavelength.

7. The method of claim 1, wherein the applying is performed by pressure-controlled direct dispensing, electrohydrodynamic (EHD) dispensing, inkjet printing, aerosol printing, screen printing, flexography printing, gravure printing, off-set printing, or a combination thereof.

8. The method of claim 1, wherein the conductive ink composition comprises: metal particles, a binder, and a solvent.

9. The method of claim 1, wherein the substrate is selected from the group consisting of Cu, Ag, Ti, Ti—Al—Ti stack, glass, Al₂O₃, BaTiO₃, AlN, TiO₂, ZrO₂, polyimide (PI), polyethylene terephthalate (PET), polyethylene naphthalate (PEN), polyethylene furandicarboxylate (PEF), polycarbonate (PC), poly(methyl methacrylate) (PMMA), cyclic olefin polymer (COP), fiber-reinforced composite, and combinations thereof.
